(19) United States
(12) Patent Application Publication
(10) Pub. No.: US 2012/0318059 A1
(43) Pub. Date: Dec. 20, 2012

(54) SENSOR DEVICE AND MANUFACTURING METHOD THEREOF

(75) Inventor: Tetsuya OTSUKI, Fujimi-machi (JP)

(73) Assignee: SEIKO EPSON CORPORATION, Tokyo (JP)

(21) Appl. No.: 13/493,540

(22) Filed: Jun. 11, 2012

(30) Foreign Application Priority Data
Jun. 16, 2011 (JP) 2011-133937

(51) Int. Cl. G01P 3/14; H01L 21/50

(52) U.S. Cl. 73/504.12; 438/123; 257/E21.499

(57) ABSTRACT

A sensor device includes an IC chip as a semiconductor device having a first electrode and a second electrode on a first surface, a frame-like fixing member provided to surround the first electrode and the second electrode, a vibration gyro element as a vibrating piece electrically connected to the first electrode, a lid as a lid body bonded to the first surface via the fixing member and forming a space that covers the vibration gyro element, and a lead wire electrically connected to the second electrode and extending through inside (between an IC-side fixing member and a lid-side fixing member in the embodiment) of the fixing member to outside of the space.

The entire disclosure of Japanese Patent Application No. 2011-133937, filed Jun. 16, 2011 is expressly incorporated by reference herein.

### BACKGROUND

1. Technical Field

The present invention relates to a sensor device and a manufacturing method of the sensor device.

2. Related Art

In related art, in sensor devices that sense acceleration, angular velocities, or the like, a sensor device including a vibrating piece (sensor element) and a circuit element such as a drive circuit that drives the vibrating piece has been known.

For example, Patent Document 1 (JP-A-2005-292079) discloses a gyro sensor as a sensor device including a vibration gyro element as a vibrating piece (gyro vibrating piece) and a semiconductor device as a circuit element.

In the configuration of the gyro sensor described in Patent Document 1, the semiconductor device is fixed to a support substrate and electrically connected to a lead wiring part formed on the support substrate. Further, a sensor element (vibration gyro element) is connected to a lead wire fixed to the support substrate, and thereby, placed to superpose on the semiconductor device in a plan view with an air gap held between the semiconductor device and itself and sealed within a package. In this manner, the semiconductor device and the sensor element are longitudinally arranged and downsizing (smaller area) of the sensor device can be realized.

Like the gyro sensor described in Patent Document 1, in the sensor devices having the configuration in which the sensor element (vibrating piece) and an IC chip (semiconductor circuit element) are longitudinally arranged and sealed, ceramic packages have been widely used in the past.

However, the ceramic package has been generally expensive and becomes a bottleneck in cost reduction of the sensor device.

Further, there has been a problem that the thickness of the package is an obstacle to reduction in thickness of the sensor device.

### SUMMARY

An advantage of some aspects of the invention is to solve at least apart of the problems described above, and the invention can be implemented as the following forms or application examples.

### Application Example 1

This application example is directed to a sensor device including a semiconductor device having a first electrode and a second electrode on a first surface, a frame-like fixing member provided to surround the first electrode and the second electrode, a vibrating piece electrically connected to the first electrode, a lid body bonded to the first surface via the fixing member and forming a space that covers the vibrating piece, and a lead wire electrically connected to the second electrode and extending through inside of the fixing member to outside of the space.

According to the sensor device having the configuration, unlike the sensor device in related art, no package is used and the semiconductor device itself forms a part of the outer shape of the sensor device, and thus, significant reduction in thickness may be realized and the lower cost may be realized.

### Application Example 2

This application example is directed to the sensor device according to the above application example, which further includes an external mounting terminal on a second surface opposite to the first surface of the semiconductor device, wherein the lead wire is electrically connected to the external mounting terminal via a third surface connecting the first surface and the second surface.

According to the configuration, an ultrathin package-type sensor device in which the second surface of the semiconductor device is used as an outer bottom surface of the sensor device and the vibrating piece is sealed by the lid body may be provided.

### Application Example 3

This application example is directed to the sensor device according to the above application example, which further includes an insulating resin layer between at least one of the external mounting terminal and the lead wire and at least one of the second surface and the third surface.

According to the configuration, the insulating resin layer intervenes between the lead wire and the semiconductor device, and thus, the lead wire does not directly contact a corner part of the semiconductor device. Further, the insulating resin layer serves as a backing of the lead wire, and thus, stress on bent parts of the lead wire may be reduced and cracking and braking of the wires may be suppressed.

Furthermore, a force on the lead wire is relaxed by the insulating resin layer and an impact on the semiconductor device or the like is suppressed, and thus, damage on the semiconductor device may be suppressed. In addition, in the case where the insulating resin layer intervenes between the second surface and the external mounting terminal, the heat and impact when mounted on an external substrate are relaxed by the insulating resin layer and the stress on the semiconductor device may be reduced.

### Application Example 4

This application example is directed to the sensor device according to the above application example, which further includes an insulating resin layer between the second electrode and the first surface.

According to the configuration, because of elasticity of the insulating resin layer, a force such as an impact applied from outside may be relaxed and may be hard to be transmitted to the vibrating piece, and deterioration in characteristics such as a frequency-temperature characteristic of the vibrating piece may be suppressed.

### Application Example 5

This application example is directed to the sensor device according to the above application example, which further includes a plated layer on a surface of the lead wire different from a surface of the lead wire being in contact with the fixing member.

The inventors have found that, in the case where low-melting-point glass is used as the fixing member, when a plated layer of gold or the like is formed on the lead wire, adhesion between the lead wire and the fixing member becomes significantly lower.

According to the configuration, particularly, when the low-melting-point glass is used as the fixing member, adhesion failure between the lead wire and the fixing member may be avoided.

### Application Example 6

This application example is directed to a manufacturing method of a sensor device including providing a frame-like fixing member surrounding a first electrode and a second electrode on a first surface of a semiconductor device having the first electrode and the second electrode on the first surface, electrically connecting a vibrating piece to the first electrode, electrically connecting a first end of a lead wire to the second electrode and providing the lead wire in contact with the fixing member between a second end opposite to the first end and the first end, and bonding a lid body forming a space that covers the vibrating piece to the first surface via the fixing member.

According to the manufacturing method of the sensor device, the semiconductor device itself forms a part of the outer shape of the sensor device, and thus, the sensor device with the significantly reduced thickness may be realized. Further, no package is used unlike the sensor device in related art, and thus, the sensor device may be provided at the lower cost.

### Application Example 7

This application example is directed to the manufacturing method of a sensor device according to the above application example, wherein the providing of the lead wire includes providing an external mounting terminal on a second surface opposite to the first surface of the semiconductor device and electrically connecting the lead wire to the external mounting terminal via a third surface connecting the first surface and the second surface.

According to the configuration, an ultrathin package-type sensor device in which the second surface of the semiconductor device is used as an outer bottom surface of the sensor device and the vibrating piece is sealed by the lid body may be manufactured.

### Application Example 8

This application example is directed to the manufacturing method of a sensor device according to the above application example which further includes providing an insulating resin layer between at least one of the external mounting terminal and the lead wire and at least one of the second surface and the third surface before providing the lead wire.

According to the configuration, the insulating resin layer intervenes between the lead wire and the semiconductor device, and thus, the lead wire does not directly contact a corner part of the semiconductor device. Further, the insulating resin layer serves as a backing of the lead wire, and thus, stress on bent parts of the lead wire may be reduced and cracking and braking of the wires may be suppressed. Therefore, a sensor device with high resistance to impact and high reliability may be provided.

### Application Example 9

This application example is directed to the manufacturing method of a sensor device according to the above application example, which further includes providing a plated layer on a surface different from a surface of the lead wire in contact with the fixing member.

According to the configuration, particularly, when low-melting-point glass is used, adhesion failure between the lead wire and the fixing member may be avoided. Therefore, a sensor device with high reliability may be provided.

### BRIEF DESCRIPTION OF THE DRAWINGS

The invention will be described with reference to the accompanying drawings, wherein like numbers reference like elements.

FIGS. 1A and 1B are schematic views showing a general configuration of one embodiment of a sensor device, and FIG. 1A is a plan view as seen down from a side of a vibration gyro element as a vibrating piece (from above), and FIG. 1B is a sectional view along A-A line of FIG. 1A.

FIG. 2 is a schematic plan view of the sensor device as seen from a bottom side (from underneath).

FIG. 3 is a schematic plan view for explanation of an operation of the vibration gyro element as a vibrating piece .

FIGS. 4A and 4B are schematic plan views for explanation of the operation of the vibration gyro element.

FIG. 5 is a flowchart showing a manufacturing method of the sensor device.

FIGS. 6A and 6B are schematic views showing a general configuration of modified example 1 of the sensor device, and FIG. 6A is a plan view as seen down from the vibration gyro element side (from above), and FIG. 6B is a sectional view of FIG. 6A.

FIG. 7 is a plan view schematically showing a flexible substrate on which lead wires used for the sensor device of modified example 1 are formed.

FIGS. 8A and 8B are schematic views showing a general configuration of modified example 2 of the sensor device, and FIG. 8A is a plan view as seen down from the vibration gyro element side (from above), and FIG. 8B is a sectional view of FIG. 8A.

### DESCRIPTION OF EXEMPLARY EMBODIMENTS

As below, embodiments implementing the invention will be explained with reference to the drawings.

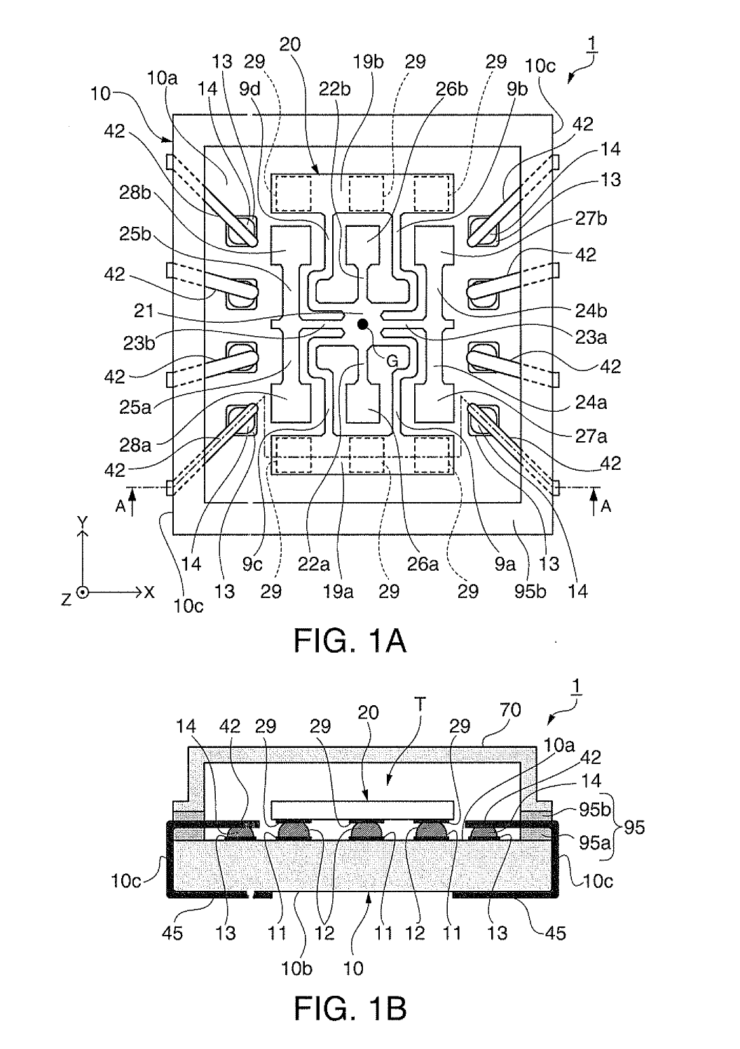

FIGS. 1A and 1B are schematic views showing a general configuration of one embodiment of a sensor device, and FIG. 1A is a plan view as seen down from a side of a vibration gyro element as a vibrating piece (from above), and FIG. 1B is a sectional view along A-A line of FIG. 1A. Note that, in FIG. 1A, illustration of a lid as a lid body is omitted for convenience of explanation of a main part of the sensor device.

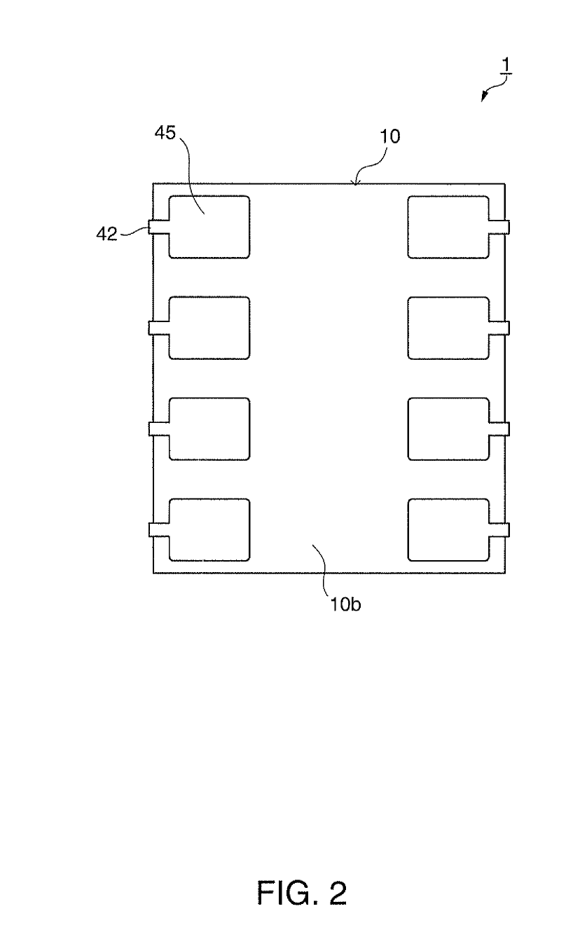

Further, FIG. 2 is a schematic plan view of the sensor device as seen from a bottom side (from underneath).

As shown in FIGS. 1A and 1B, a sensor device 1 includes an IC chip 10 as a semiconductor device in which a first electrode 11 and a second electrode 13 are provided on a first surface 10a, a vibration gyro element (gyro vibrating piece) 20 as a vibrating piece electrically connected to the first electrode 11 and held on the first surface 10a of the IC chip 10, a lid 70 as a lid body joined onto the first surface 10a via a frame-like fixing member 95 provided to surround the vibration gyro element 20 and forming a space T that covers the vibration gyro element 20, and lead wires 42 electrically connected to the second electrode 13 and extending to the outside of the space T through inside of the fixing member 95.

First, the vibration gyro element 20 as a vibrating piece in the sensor device 1 will be explained in detail.

The vibration gyro element 20 is formed using a piezoelectric material of quartz as a base material (a material forming a main part). The quartz has an X-axis called “electrical axis”, a Y-axis called “mechanical axis”, and a Z-axis called “optical axis”.

Further, the vibration gyro element 20 is cut out along a plane defined by the X-axis and the Y-axis orthogonal to each other in crystal axes and processed into a flat plate and has a predetermined thickness in the Z-axis direction orthogonal to the plane. Note that the predetermined thickness is appropriately set according to an oscillation frequency (resonance frequency), an outer size, workability, or the like.

Furthermore, the flat plate forming the vibration gyro element 20 may allow errors of cutout angles from quartz in some margins with respect to the X-axis, the Y-axis, and the Z-axis. For example, the plate rotated in a range from 0 to 2 degrees around the X-axis and cut out may be used. The same is applicable with respect to the Y-axis and the Z-axis.

The vibration gyro element 20 is formed by etching (wet etching or dry etching) using a photolithography technology. A plurality of the vibration gyro elements 20 may be obtained from one quartz wafer.

As shown in FIG. 1A, the vibration gyro element 20 of the embodiment has a configuration called “double-T type” . Specifically, the vibration gyro element 20 has a base part 21 located in a center part, a pair of detection vibrating arms 22a, 22b as vibrating parts extended from the base part 21 along the Y-axis, a pair o connecting arms 23a, 23b extended from the base part 21 along the X-axis orthogonally to the detection vibrating arms 22a, 22b and respective pairs of drive vibrating arms 24a, 24b, 25a, 25b as the vibrating parts extended from the end sides of the respective connecting arms 23a, 23b along the Y-axis in parallel to the detection vibrating arms 22a, 22b.

The respective detection vibrating arms 22a, 22b have spindle parts 26a, 26b in nearly rectangular shapes with larger widths (larger lengths in the X-axis direction) than other parts at the end sides. Similarly, the two pairs of drive vibrating arms 24a, 24b and drive vibrating arms 25a, 25b have spindle parts 27a, 27b and spindle parts 28a, 28b in nearly rectangular shapes with larger widths than other parts at the end sides, respectively. By the spindle parts 26a, 26b, 27a, 27b, 28a, 28b, the vibration gyro element 20 may improve detection sensitivity for angular velocities while being downsized.

Further, the vibration gyro element 20 includes a pair of fixing parts 19a, 19b. Of them, one fixing part 19a is provided in a positive direction of the Y-axis with respect to one detection vibrating arm 22a of the pair of detection vibrating arms 22a, 22b. Furthermore, the other fixing part 19b is provided in a negative direction of the Y-axis with respect to the other detection vibrating arm 22b of the pair of detection vibrating arms 22a, 22b. The lengths of the respective fixing parts 19a, 19b in the X-axis direction are larger than the lengths of the spindle parts 26a, 26b of the respective detection vibrating arms 22a, 22b in the X-axis direction, and nearly equal to a total of the lengths of the pair of connecting arms 23a, 23b and the base part 21 in the X-axis direction, for example. Note that, in the illustrated example, the planar shapes of the respective fixing parts 19a, 19b are nearly rectangular, however, not limited to those. The fixing parts 19a, 19b are provided separately from the respective detection vibrating arms 22a, 22b and the respective drive vibrating arms 24a, 24b, 25a, 25b. The respective fixing parts 19a, 19b are parts fixed to the IC chip 10 via bonding members 12.

As shown in FIG. 1A, a pair of beams 9a, 9c are provided between the base part 21 and the one fixing part 19a. Of them, one beam 9a is extended from the base part 21 through between the detection vibrating arm 22a and the drive vibrating arm 24a and connected to the fixing part 19a, and the other beam 9c is extended from the base part 21 through between the detection vibrating arm 22a and the drive vibrating arm 25a and connected to the fixing part 19a.

Similarly, a pair of beams 9b, 9d are provided between the base part 21 and the other fixing part 19b. Of them, one beam 9b is extended from the base part 21 through between the detection vibrating arm 22b and the drive vibrating arm 24b and connected to the fixing part 19b, and the other beam 9d is extended from the base part 21 through between the detection vibrating arm 22b and the drive vibrating arm 25b and connected to the fixing part 19b. The respective beams 9a, 9b, 9c, 9d may have S-shapes as shown in the drawing. As described above, the respective fixing parts 19a, 19b and the base part 21 are connected by the beams 9a, 9b, 9c, 9d having elongated and meandering shapes, and thereby, a main part of the vibration gyro element 20 may obtain elasticity in the X-direction and the Y-axis direction.

The center of the base part 21 may be a center of gravity Gas a position of the center of gravity of the vibration gyro element 20. The X-axis, the Y-axis, and the Z-axis are orthogonal to one another and pass through the center of gravity G. The vibration gyro element 20 may be point-symmetric with respect to the center of gravity G. That is, the vibration gyro element 20 may be plane-symmetric with respect to an XZ-plane, and plane-symmetric with respect to a YZ-plane.

Further, in the vibration gyro element 20, detection electrodes (not shown) are formed on the detection vibrating arms 22a, 22b and drive electrodes (not shown) are formed on the drive vibrating arms 24a, 24b, 25a, 25b.

The vibration gyro element 20 forms a detection vibration system that detects angular velocities with the detection vibrating arms 22a, 22b and forms a drive vibration system that drives the vibration gyro element 20 with the connecting arms 23a, 23b and the drive vibrating arms 24a, 24b, 25a, 25b.

The vibration gyro element 20 is provided at the first surface 10a side of the IC chip 10 to overlap with the IC chip 10 in the plan view.

Lead electrodes 29 led from the respective detection electrodes and the respective drive electrodes are formed on surfaces facing the IC chip 10 of the respective fixing parts 19a, 19b of the vibration gyro element 20.

Next, the IC chip 10 as a semiconductor device will be explained according to the drawings.

In the IC chip 10, an integrated circuit (not shown) including semiconductor devices such as a transistor and a memory device at the first surface 10a side is formed. In the integrated circuit, a drive circuit for drive-vibrates the vibration gyro element 20 and a detection circuit that detects detection-vibration generated in the vibration gyro element 20 when an angular velocity is applied are provided.

The IC chip 10 includes the pluralities of the first electrodes (electrode pads) 11 and second electrodes 13 provided at the first surface 10a side as shown in FIGS. 1A, 1B, and 2.

The first electrodes 11 and the second electrodes 13 are formed to directly conduct to the integrated circuit of the IC chip 10. The first electrodes 11 are connected to the vibration gyro element 20 and the second electrodes 13 are connected to an external mounting board. The first electrodes 11 of the embodiment are provided in regions overlapping with the lead electrodes 29 of the vibration gyro element 20 in the plan view.

Further, on the first surface 10a, an insulating film (not shown) as a passivation film is formed. The insulating film may be formed using an inorganic insulating material such as silicon oxide (SiO₂) or silicon nitride (Si₃N₄) or a resin such as a polyimide resin, a silicone modified polyimide resin, an epoxy resin, a silicone modified epoxy resin, an acrylic resin, a phenol resin, BCB (benzocyclobutene), or PBO (polybenzoxazole).

The first electrodes 11, the second electrodes 13, or other electrodes may be formed using titanium (Ti), titanium nitride (TiN), aluminum (Al), copper (Cu), or an alloy containing them. Specifically, regarding the second electrodes 13, it is preferable to perform nickel (Ni) or gold (Au) plating on surfaces thereof for improvement of bonding capability when the electrodes are bonded to the lead wires, which will be described later. In this manner, reduction in contact capability and bonding capability due to rust may be prevented.

Further, the first electrodes 11, the second electrodes 13, or other electrodes may be subjected to uppermost surface treatment such as solder plating or solder pre-coating.

In a peripheral edge part of the first surface 10a, the frame-like fixing member 95 for bonding of the lid 70 as a lid body is provided. In the embodiment, in the state before the lid 70 is bonded to the IC chip 10, two layers of an IC-side fixing member 95a provided at the IC chip 10 side and a lid-side fixing member 95b provided at the lid 70 side form the fixing member 95.

The fixing member 95 is provided to surround the first electrodes 11 and the second electrodes 13 in the plan view, and provided to surround the vibration gyro element 20 in the state in which the first electrodes 11 and the vibration gyro element 20 are electrically connected and fixed onto the IC chip 10.

For the fixing member 95, an insulating bonding material is used, and various materials may be chosen according to a material of the lid 70. In the embodiment, glass is used for the lid 70, and the fixing member 95 is formed using low-melting-point glass preferable for bonding of the glass and silicon as the material of the IC chip 10. In addition, for the fixing member 95, for example, a resin adhesive or the like may be used.

As shown in FIG. 2, on a second surface (bottom surface) 10b opposite to the first surface (10a) of the IC chip 10, plural external mounting terminals 45 used for mounting the sensor device 1 on an external substrate are arranged.

Note that, part of the plural external mounting terminals 45 may be used not only for mounting but also as test terminals used for operation check and measurement of characteristic values of the sensor device 1 or writing terminals as input terminals for writing data in the IC chip 10.

In FIGS. 1A and 1B, one ends of lead wires 42 formed using a metal such as copper (Cu) are bonded to the plural second electrodes 13 via conducting bonding members 14. For the bonding members 14, various conducting bonding members such as a conducting adhesive of silver paste, a metal bump, solder, or a resin core bump having an electrode film formed on a surface of a resin block may be used.

The respective lead wires 42 extend toward the peripheral edge side of the IC chip 10 through inside (between the IC-side fixing member 95a and the lid-side fixing member 95b in the embodiment) of the fixing member 95 to the outside of the first surface 10a. The other ends of the respective lead wires 42 extending to the outside of the first surface 10a are bent along third surfaces (side surfaces) 10c connecting the first surface 10a and the second surface 10b of the IC chip 10, bent from the third surfaces 10c to the second surface 10b again, and connected to the corresponding external mounting terminals 45.

Plated layers (not shown) are provided on surfaces different from surfaces in contact with the fixing member 95 (the IC-side fixing member 95a and the lid-side fixing member 95b) of the lead wires 42. The plated layers are metal layers formed by plating and, for example, plated layers in which nickel-gold (Ni—Au) are stacked or the like may be used, and have an advantage that the bonding strength is improved in bonding between the lead wires 42 and the second electrodes 13 via the bonding members 14.

It is known that adhesion between the fixing member 95 and the lead wires 42 (plated layers) is significantly reduced depending on the combination of the fixing member 95 and the plated layers, and formation of the plated layers to avoid the surfaces in contact with the fixing member 95, here, is for avoiding the reduction. Specifically, in the case where the low-melting-point glass is used for the fixing member 95 as in the embodiment, it is known that the adhesion to the low-melting-point glass is inhibited by the plated layers formed on the surfaces of the metals such as the lead wires 42.

On the first electrodes 11, the corresponding lead electrodes 29 provided in the fixing parts 19a, 19b of the vibration gyro element 20 are positioned and bonded via the conducting bonding members 12. Thereby, in the IC chip 10, the integrated circuits led out from the respective first electrodes 11 are electrically connected to the vibration gyro element 20 via the bonding members 12 and the lead electrodes 29. In this regard, a gap is provided between the vibrating part of the vibration gyro element 20 and the IC chip 10 depending on the heights of the bonding members 12 (heights after bonding).

Onto the IC chip 10 to which the vibration gyro element 20 has been bonded, the lid 70 as a lid body is bonded via the fixing member 95. Thereby, the space T covering the vibration gyro element 20 bonded onto the IC chip 10 is formed and the vibration gyro element 20 is sealed in the space T. In this regard, according to need, the space T formed by the IC chip 10 and the lid 70 may be air-tightly sealed in a decompressed space or an inert gas atmosphere.

According to the sensor device 1 having the configuration, an ultrathin package-type sensor device 1 in which the second surface 10b of the IC chip 10 as the semiconductor device is used as an outer bottom surface and the vibration gyro element 20 as the vibrating piece is air-tightly sealed by the lid 70 may be provided.

Further, no package is used unlike the device in related art, and the sensor device 1 may be provided at low cost.

### Operation of Vibration Gyro Element

Here, an operation of the vibration gyro element 20 of the sensor device 1 will be explained.

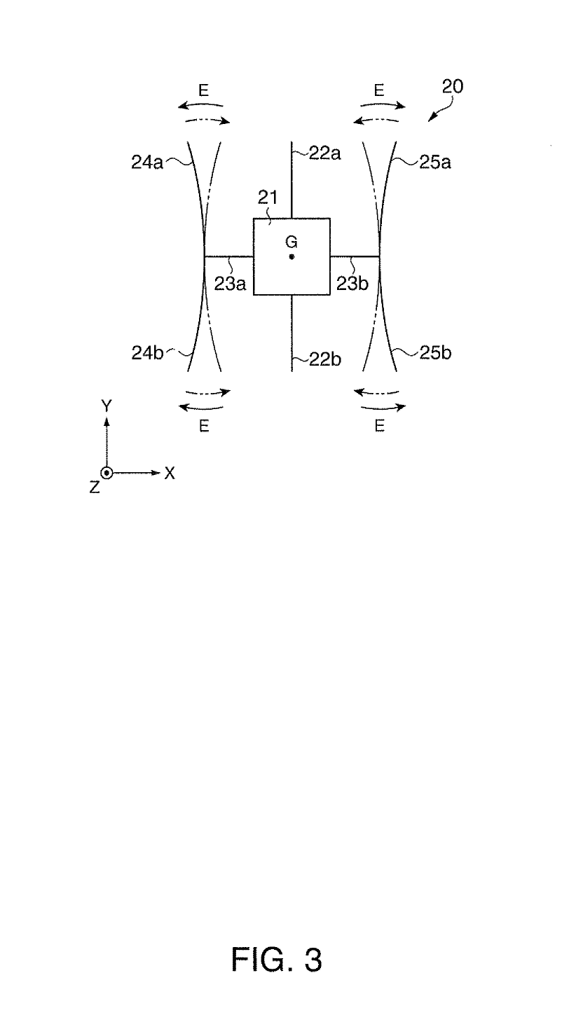

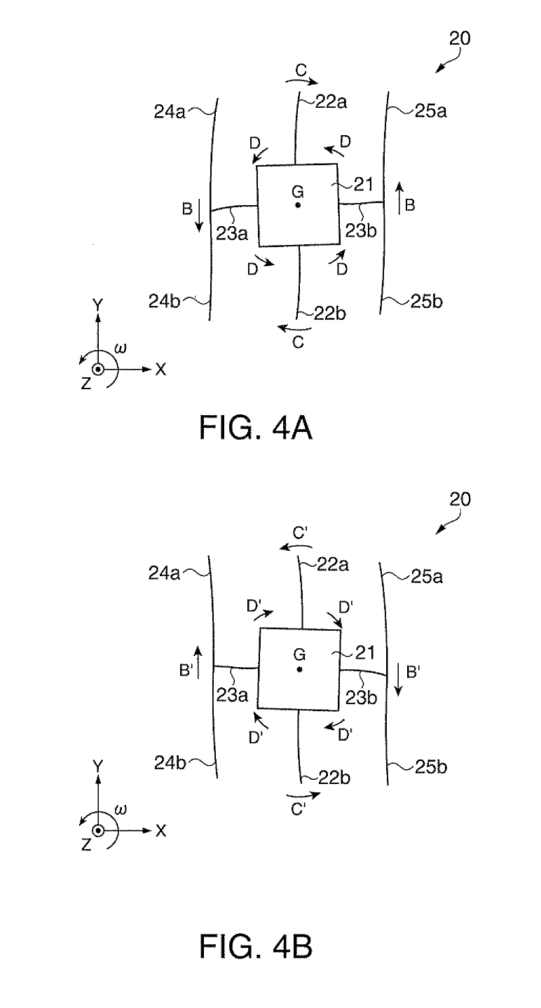

FIGS. 3, 4A, and 4B are schematic plan views for explanation of the operation of the vibration gyro element. FIG. 3 shows a drive-vibration state, and FIGS. 4A and 4B show a detection-vibration state when an angular velocity is applied.

Note that, in FIGS. 3, 4A, and 4B, the respective vibrating arms are shown by lines for simple representation of vibration states.

First, the drive-vibration state of the vibration gyro element 20 will be explained.

In FIG. 3, when a drive signal is applied from the integrated circuit (drive circuit) of the IC chip 10, under the condition that no angular velocity is applied, the vibration gyro element 20 perform flexural vibration in directions shown by arrows E with the drive vibrating arms 24a, 24b, 25a, 25b. The flexural vibration repeats a vibration mode shown by solid lines and a vibration mode shown by chain double-dashed lines at a predetermined frequency.

Then, when an angular velocity ω is applied to the vibration gyro element 20 during the drive-vibration, the vibration gyro element 20 performs vibration as shown in FIGS. 4A and 48.

First, as shown in FIG. 4A, Coriolis forces in directions of arrows B act on the drive vibrating arms 24a, 24b, 25a, 25b and the connecting arms 23a, 23b forming a drive-vibration system. Concurrently, the detection vibrating arms 22a, 22b are deformed in directions of arrows C in response to the Coriolis forces in the directions of arrows B.

Then, as shown in FIG. 4B, forces returning in directions of arrows B′ act on the drive vibrating arms 24a, 24b, 25a, 25b and the connecting arms 23a, 23b. Concurrently, the detection vibrating arms 22a, 22b are deformed in directions of arrows C′ in response to the forces in the directions of arrows B′.

The vibration gyro element 20 alternately repeats the series of operation and new vibration is excited.

Note that the vibration in the directions of arrows B and 8′ is vibration in the circumferential direction with respect to the center of gravity G. Further, in the vibration gyro element 20, the detection electrodes formed on the detection vibrating arms 22a, 22b detect distortion of quartz generated by vibration, and thereby, the angular velocity is obtained.

### Manufacturing Method of Sensor Device

Next, a manufacturing method of the sensor device will be explained.

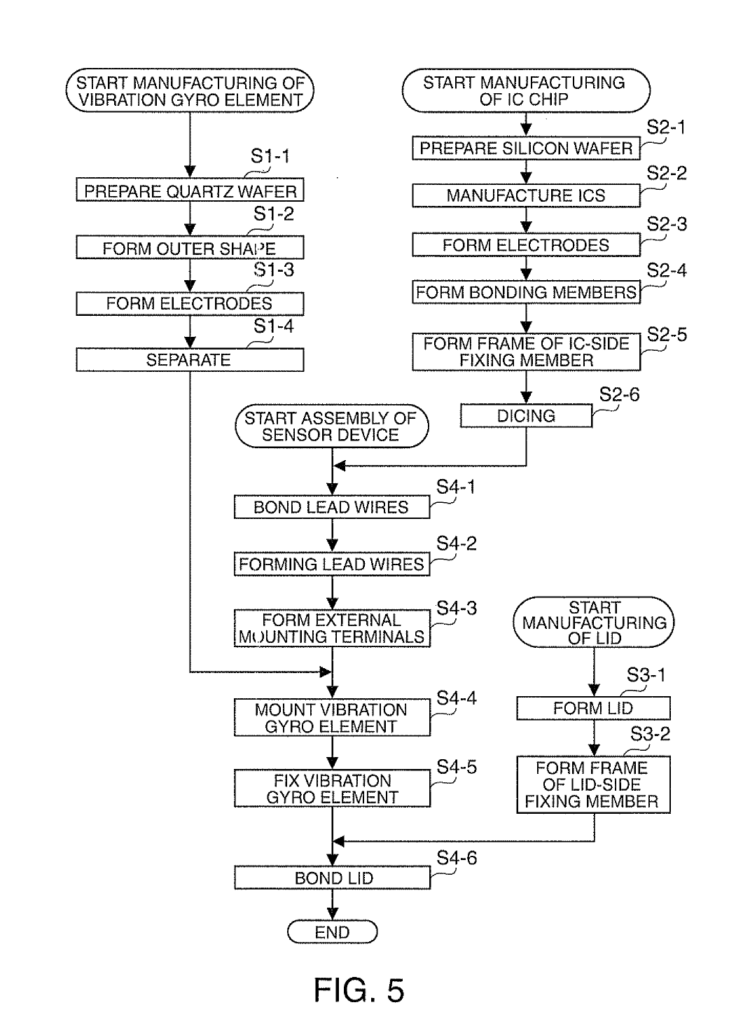

FIG. 5 is a flowchart showing one embodiment of the manufacturing method of the sensor device 1.

FIG. 5 shows step S1-1 to step S1-4 of the manufacturing process of the vibration gyro element 20, step S2-1 to step S2-6 of the manufacturing process of the IC chip 10, step S3-1 to step S3-2 of the manufacturing process of the lid 70, and step S4-1 to step S4-6 of the assembly process of the sensor device 1. As below, the method will be explained from the preceding process.

In the manufacturing of the sensor device 1 of the embodiment, first, the process of manufacturing plural vibration gyro elements 20 from a quartz wafer will be explained.

In the manufacturing of the vibration gyro element 20, a method of obtaining plural vibration gyro elements 20 at the same time by forming plural vibration gyro elements 20 arranged on a large-sized quartz wafer, and then, cutting the wafer into individual vibration gyro elements 20 by dicing or splitting off (separation) may be employed.

### Manufacturing of Vibration Gyro Element

First, as shown by step S1-1, a large-sized quartz wafer cut out at a predetermined cut angle with respect to the crystal axis and polished to a desired thickness and a surface condition is prepared. Then, as shown by step S1-2, outer shapes of the plural vibration gyro elements are formed on the quartz wafer by wet etching using photolithography.

Specifically, first, a corrosion-resistant film containing chromium and gold, for example, that may be an etching mask is formed on the entire of both principal surfaces of the quartz wafer by sputtering or the like, then, a photoresist is applied thereto, a mask for outer shape patterning of the vibration gyro elements is placed on the photoresist, and the outer shape pattern is exposed to light.

Then, after development of removing the exposed parts by exposure of the photoresist, the wafer is immersed in an etchant, the corrosion-resistant film in the parts from which the exposed photoresist has been removed is etched, and an etching mask for outer shape formation of the vibration gyro elements of the corrosion-resistant film is formed on the quartz wafer.

Then, the quartz wafer on which the etching mask for outer shape formation of the vibration gyro elements has been formed is immersed in an etchant of a hydrogen fluoride solution and an ammonium fluoride solution, for example, and etched until the parts corresponding to the outer shapes of the vibration gyro elements 20 of the quartz substrate penetrate.

Note that the outer shapes of the vibration gyro elements are connected by perforated split-off parts not to be completely separated from the quartz wafer, and thereby, the subsequent steps may be efficiently moved in the quartz substrate (wafer) state.

Then, as shown by step S1-3, the etching mask for outer shape formation of the vibration gyro elements of the corrosion-resistant film is peeled off.

Then, as shown by step S1-3, electrode formation of the above described drive electrodes, detection electrodes, lead electrodes 29 is performed by sputtering, evaporation, or the like.

The electrode formation may be performed by forming a chromium layer, for example, as a base layer on the surface of the quartz wafer on which the outer shapes of the vibration gyro elements 20 have been formed by sputtering or evaporation, and stacking a gold layer thereon or patterning a metal stacked by photolithography in a desired electrode pattern shape.

Then, as shown by step S1-4, the plural vibration gyro elements 20 formed on the quartz wafer are separated by dicing, splitting them off from the quartz wafer via the above describe perforation, or the like.

### Manufacturing of IC Chip

Next, the process of manufacturing the IC chip 10 as a semiconductor device will be explained.

In the manufacturing of the IC chip 10, like the manufacturing of the vibration gyro element 20, a method of obtaining plural IC chips 10 at the same time by forming plural IC chips 10 arranged on a large-sized silicon wafer, and then, dicing the wafer may be employed.

First, as shown by step S2-1, a silicon wafer is prepared. Then, as shown by step S2-2, IC manufacturing of forming plural IC chips 10 at the same time on the silicon wafer using a typical semiconductor manufacturing process is performed.

Then, as shown by step S2-3, electrode formation of the above described first electrodes 11, second electrodes 13, etc. is performed by sputtering or evaporation. After the electrode formation, an insulating film (passivation film) is formed on the first surface 10a, and opening parts for exposure of part of the first electrodes 11 and the second electrodes 13 are formed.

Then, as shown by step S2-4, the conducting bonding members 12 for bonding to the vibration gyro element 20 are formed on the first electrodes 11 and the conducting bonding members 14 for connection to the lead wires 42 are formed on the second electrodes 13. For the bonding members 14, various conducting bonding members of a metal bump, a solder bump, or a resin core bump having an electrode film formed on a. surface of a resin block may be used, and they may be formed using a known method.

Note that, for the bonding members 12, 14, a conducting adhesive of Ag paste or the like may be used, and, in this case, formation of the bonding members 12, 14 is performed immediately before a lead wire bonding step (step S4-1) and a vibration gyro element mounting step (step S4-4), which will be described later.

Then, as shown by step S2-5, the IC-side fixing member 95a as a part of the frame-like fixing member 95 is formed in the peripheral edge part of the first surface 10a to surround the first electrodes 11 and the second electrodes 13 in the plan view. For the fixing member 95, an insulating bonding material is used and various materials may be chosen according to the material of the lid 70. In the embodiment, glass is used for the lid 70, and the fixing member 95 is formed using low-melting-point glass preferable for bonding of the glass and silicon as the material of the IC chip 10.

Then, as shown by step S2-6, the IC chip 10 is diced and separated.

### Manufacturing of Lid

Next, the process of manufacturing the lid 70 will be explained.

First, as shown by step S3-1, the lid 70 is formed.

In the embodiment, the lid 70 is formed using glass. The glass lid 70 may be formed by etching using photolithography, sandblasting, or the like.

Then, as shown by step S3-2, the lid-side fixing member 95b as a part of the fixing member 95 using the same material as that of the IC-side fixing member 95a is formed in the peripheral edge part of the surface of the lid 70 at the side bonded to the IC chip 10.

### Assembly of Sensor Device

Next, the process of assembly of the sensor device 1 will be explained.

In the process of assembly of the sensor device, first, as shown by step S4-1, one ends of the lead wires 42 are bonded to the second electrodes 13 of the IC chip 10.

The lead wires 42 may be formed by etching of a metal such as copper using photolithography. In the sensor device 1 of the embodiment, an example in which the lead wires 42 are formed integrally with the external mounting terminals 45 is shown (see FIGS. 1A, 1B, and 2).

On surfaces of the lead wires 42, plated layers with stacked nickel-gold, for example, are formed by plating. In the formation of the plated layers, the plating is performed after a plating mask is provided, for example, so that the plate may not be precipitated on the surfaces of the lead wires 42 in contact with the fixing member 95 (the IC-side fixing member 95a and the lid-side fixing member 95b).

The one ends of the lead wires 42 formed in the above described manner are bonded to the second electrodes 13 via the conducting bonding members 14. For the bonding members 14, various conducting bonding members such as a conducting adhesive of silver paste, a metal bump, solder, or a resin core bump having an electrode film formed on the surface of a resin block may be used.

Next, as shown by step S4-2, forming of the lead wires 42 is performed. In the embodiment, the respective lead wires 42 with the one ends bonded to the second electrodes 13 are extended toward the peripheral edge side of the IC chip 10 through inside (on the IC-side fixing member 95a at the step) of the fixing member 95, bent along the third surfaces (side surfaces) 10c connecting the first surface 10a and the second surface 10b of the IC chip 10 at the ends of the first surface 10a, and bent from the third surfaces 10c to the second surface 10b again.

Then, the external mounting terminals 45 are fixed to predetermined locations on the second surface 10b for forming external mounting terminals (step S4-3).

Then, as shown by step S4-4, the lead electrodes 29 are positioned on the bonding members 12 on the first electrodes 11, and the vibration gyro element 20 is mounted on the IC chip 10.

Then, as shown by step S4-5, bonding of the first electrodes 11 and the lead electrodes 29 is performed via the bonding members 12 for electrical connection, and the vibration gyro element 20 is fixed onto the IC chip 10 by the bonding members 12.

Then, as shown by step S4-6, on the IC chip 10 to which the vibration gyro element 20 has been bonded, the lid 70 as a lid body is bonded via the fixing member 95. Specifically, on the IC-side fixing member 95a that has been provided in the peripheral edge part of the first surface 10a of the IC chip 10, the lid-side fixing member 95b provided on the lid 70 is positioned, with the parts of the lead wires 42 being interposed therebetween, predetermined temperature and pressure are applied thereto, and thereby, fixing of the IC chip 10 and the lid 70 is performed via the fixing member 95 in which the IC-side fixing member 95a and the lid-side fixing member 95b are integrally fused.

In this regard, according to need, the space T formed by the IC chip 10 and the lid 70 may be air-tightly sealed in a decompressed space or an inert gas atmosphere.

According to the manufacturing method of the sensor device 1, a thin sensor device using the second surface 10b of the IC chip 10 as a semiconductor device as an outer bottom surface may be manufactured at low cost.

The sensor device of the embodiment may be implemented as the following modified examples.

### Modified Example 1

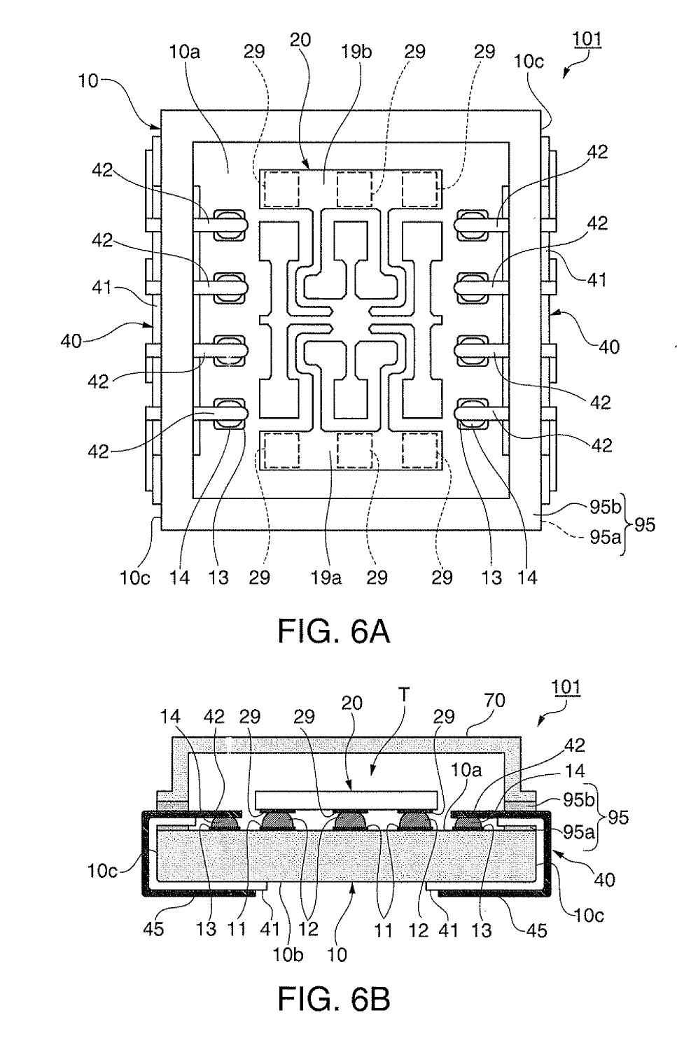

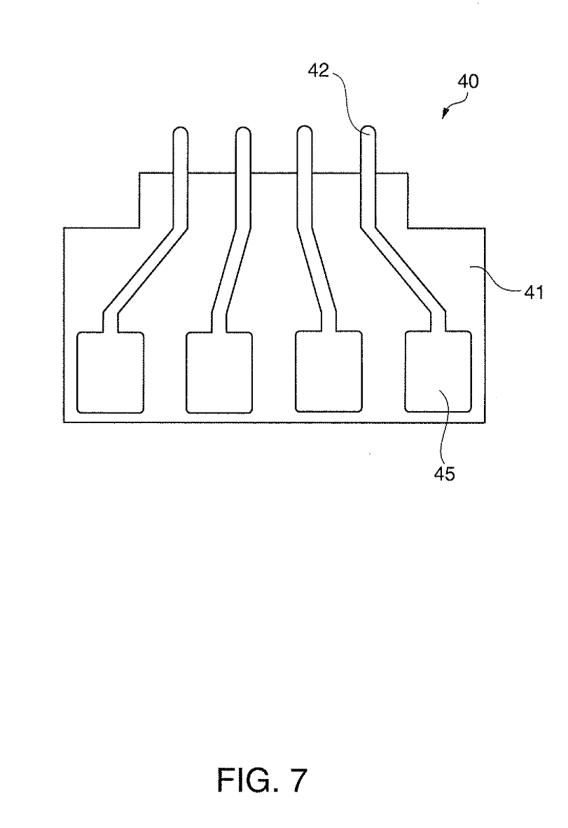

Modified example 1 of the sensor device will be explained using FIGS. 6A, 6B, and 7.

FIGS. 6A and 6B are schematic views showing a general configuration of modified example 1 of the sensor device, and FIG. 6A is a plan view as seen down from the vibration gyro element side (from above), and FIG. 6B is a sectional view of FIG. 6A. Further, FIG. 7 is a plan view schematically showing a flexible substrate on which the lead wires used for the sensor device of modified example 1 are formed.

Note that, in the explanation of modified example 1, the common parts with the embodiment have the same signs and their explanation will be omitted.

As shown in FIGS. 6A and 6B, a sensor device 101 of modified example 1 includes the IC chip 10, the vibration gyro element 20 held on the first surface 10a of the IC chip 10, the lid 70 bonded to cover the vibration gyro element 20 via the frame-like fixing member 95, and a flexible substrate 40 in which the lead wires 42 with one ends connected to the second electrodes 13 are formed on an insulating substrate 41 as an insulating resin layer.

As shown in FIG. 7, the flexible substrate 40 used for the sensor device 101 of modified example 1 has the plural external mounting terminals 45 and the lead wires 42 formed to extend from the respective external mounting terminals with end sides overhung from the insulating substrate 41 to the outside on the insulating substrate 41 as an insulating resin layer of polyimide or the like having flexibility and higher heat resistance. The flexible substrate 40 may be manufactured in the same manufacturing process as that of a general flexible substrate (printed wiring board) using photolithography.

The flexible substrate 40 is manufactured and prepared before the step of bonding the lead wires (step S4-1) in the sensor device assembly process in the manufacturing method of the sensor device (see FIG. 5) of the embodiment.

Returning to FIGS. 6A and GB, the ends (one ends) of the lead wires 42 of the flexible substrate 40 overhung from the insulating substrate 41 are bonded to the second electrodes 13 via the bonding members 14.

The respective lead wires 42 with the one ends bonded to the second electrodes 13 extend toward the peripheral edge side of the IC chip 10 with a backing of the insulating substrate 41 sandwiched between the first surface 10a and themselves through inside (between the IC-side fixing member 95a and the lid-side fixing member 95b) of the fixing member 95, bent along the third surfaces (side surfaces) 10c, further bent from the third surfaces 10c to the second surface 10b again, and connected to the corresponding external mounting terminals 45 on the insulating substrate 41.

According to the configuration, the insulating substrate 41 as an insulating resin layer intervenes between the lead wires 42 and the first surface 10a, the second surface 10b, and the third surfaces 10c of the IC chip, and thus, the lead wires 42 do not directly contact corner parts of the IC chip 10. Further, the insulating substrate 41 serves as the backing of the lead wires 42, and thus, stress applied to bent parts of the lead wires 42 may be reduced and cracking and braking of the wires may be suppressed.

Further, a force applied to the lead wires 42 is relaxed by the insulating substrate 41 and an impact applied to the IC chip 10 is suppressed, and defects that the IC chip 10 is chipped off etc. may be avoided. Further, in the modified example, the insulating substrate 41 also intervenes between the second surface 10b and the external mounting terminals 45, and thereby, the heat and impact when mounted on an external substrate are relaxed by the insulating substrate 41 and the stress on the IC chip 10 may be reduced.

### Modified Example 2

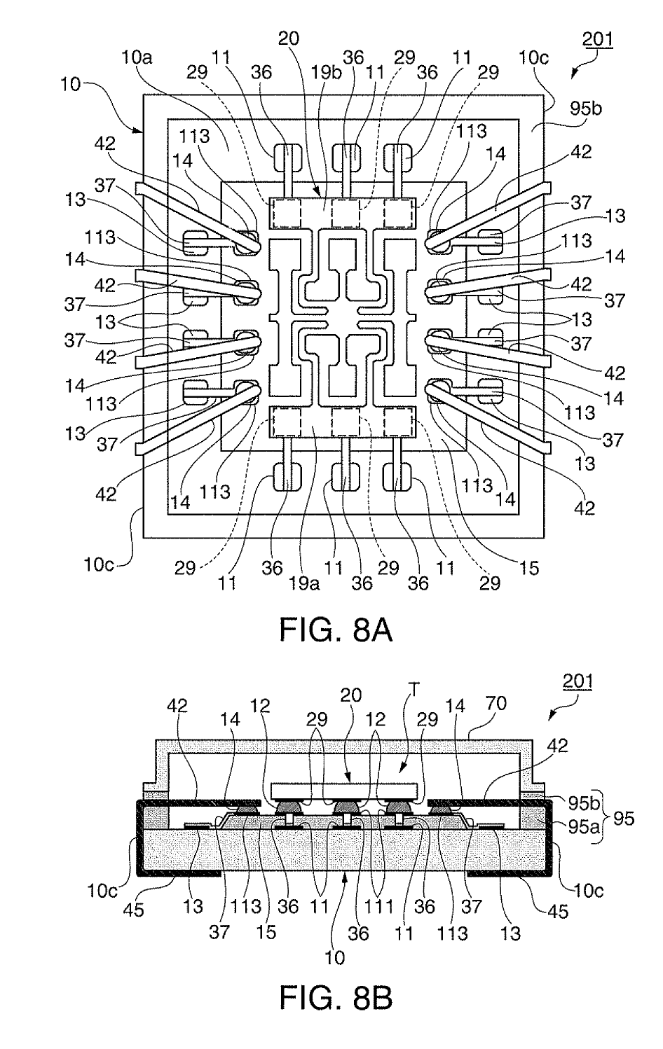

Next, modified example 2 of the sensor device will be explained using FIGS. 8A and 8B.

FIGS. 8A and 8B are schematic views showing a general configuration of modified example 2 of the sensor device, and FIG. 8A is a plan view as seen down from the vibration gyro element side (from above), and FIG. 8B is a sectional view of FIG. 8A.

Note that, in the explanation of modified example 2, the common parts with the embodiment have the same signs and their explanation will be omitted.

As shown in FIGS. 8A and 8B, a sensor device 201 of modified example 2 includes the IC chip 10, a stress relaxing layer 15 as an insulating resin layer provided on the first surface 10a of the IC chip 10, first relocation electrodes 111 provided on the stress relaxing layer 15 and electrically connected to the first electrodes 11, second relocation electrodes 113 electrically connected to the second electrodes 13, the vibration gyro element 20 electrically connected to the first relocation electrodes 111 and held on the first surface 10a, and the lid 70 bonded to cover the vibration gyro element 20 via the frame-like fixing member 95.

At the first surface 10a side of the IC chip 10, the stress relaxing layer 15 as an insulating resin layer of an insulating resin having predetermined elasticity is formed.

In locations corresponding to the plural lead electrodes 29 of the vibration gyro element 20 on the stress relaxing layer 15, the first relocation electrodes 111 electrically connected to the first electrodes 11 via wires 36 are provided.

Further, on the stress relaxing layer 15, the second relocation electrodes 113 electrically connected to the second electrodes 13 via wires 37 are provided.

These wires 36 and first relocation electrodes 111 and wires 37 and second relocation electrodes 113 form relocation wiring for relocating the first electrodes 11 and the second electrodes 13 of the integrated circuits of the IC chip 10 in locations respectively corresponding to connection locations of the lead electrodes 29 of the vibration gyro element 20 or the lead wires 42 for connection to the outside. The relocation wiring is an important component element for arranging the locations of the first relocation electrodes 111 and the second relocation electrodes 113 provided for connection to the vibration gyro element 20 and the lead wires 42 with arbitrary shift and improving the degree of freedom of the connection locations to the vibration gyro element 20 on the IC chip 10 with respect to the first electrodes 11 and the second electrodes 13 largely constrained with the locations by microfabrication design of the integrated circuits of the IC chip 10.

The stress relaxing layer 15 may be formed using an elastic resin material such as polyimide, for example. More specifically, for example, by a method of coating a photosensitive polyimide material on a surface of the insulating film of the IC chip 10 and performing patterning processing such as photolithography, its shape of the height dimension or the like may be formed with accuracy.

Further, the material of the stress relaxing layer 15 is not limited to the polyimide, but one of the materials that have been known as elastic resin materials may be applied. For example, a resin such as a silicone modified polyimide resin, an epoxy resin, a silicone modified epoxy resin, an acrylic resin, a phenol resin, a silicone resin, a modified polyimide resin, benzocyclobutene (BCB), or polybenzoxazole (PBO), may be applied.

Formation of the stress relaxing layer 15 and the relocation wiring by the first relocation electrodes 111, the second relocation electrodes 113, and the wires 36, 37 are performed before the bonding member forming step (step S2-4) of the IC chip manufacturing process in the manufacturing method of the sensor device (see FIG. 5) of the above embodiment.

That is, after the first electrodes 11 and the second electrodes 13 are formed on the first surface 10a of the IC chip 10 (step S2-3), the stress relaxing layer 15 as an insulating resin layer is formed in a predetermined location of the first surface 10a. The stress relaxing layer 15 may be formed by a method of coating a photosensitive polyimide material, for example, on the surface of the insulating film and performing patterning processing such as photolithography or the like.

Then, the relocation wiring by the first relocation electrodes 111, the second relocation electrodes 113, and the wires 36, 37 is formed on the stress relaxing layer 15.

Then, as shown by step S2-4, the bonding members 12, 14 are formed on the first relocation electrodes 111 and the second relocation electrodes 113, and subsequently, the manufacturing of the sensor device is carried forward along the flow shown in FIG. 5.

The relocation wiring by the first relocation electrodes 111, the second relocation electrodes 113, and the wires 36, 37 maybe formed using gold (Au), copper (Cu), silver (Ag), titanium (Ti), tungsten (W), titanium tungsten (TiW), titanium nitride (TiN), nickel (Ni), nickel vanadium (NiV), chromium (Cr), aluminum (Al), palladium (Pd), or the like.

Note that the first relocation electrodes 111, the second relocation electrodes 113, and the wires 36, 37 may have not only single-layer structures using the above materials but also stacking structures in combination of plural kinds of the materials, or may be formed using an alloy of plural kinds of metal materials, patterned and solidified conducting paste, or the like.

According to the configuration of the sensor device 201 of modified example 2, because of the elasticity of the stress relaxing layer 15, a force such as an impact applied from outside may be relaxed and may be hard to be transmitted to the vibration gyro element 20, and deterioration in characteristics such as a frequency-temperature characteristic of the vibration gyro element 20 may be suppressed.

As above, the embodiments of the invention by the inventors have been specifically explained, however, the invention is not limited to the above described embodiment and the modified examples thereof, but various changes may be made without departing from the scope thereof.

For example, in the embodiment, examples using quartz as the formation material of the vibration gyro device as a vibrating piece has been explained, however, piezoelectric materials other than quartz may be used. For example, aluminum nitride (AlN) , an oxide substrate of lithium niobate (LiNbO₃) lithium tantalate (LiTaO₃), lead zirconate titanate (PZT), lithium tetraborate (Li₂B₄O₇) , langasite (La₃Ga₅SiO₁₄) , or the like, a laminated piezoelectric substrate formed by laminating a piezoelectric material of aluminum nitride, tantalum pentoxide (Ta₂O₅), or the like on a glass substrate, or piezoelectric ceramics such as lead titanate zirconate (Pb(Zrx, Ti1−x)O₃), may be used.

Further, the vibrating piece may be formed using a material other than the piezoelectric materials. For example, a vibrating element may be formed using a silicon semiconductor material or the like.

Furthermore, the excitation system of drive-vibration and the detection system of detection-vibration of the vibrating element are not limited to the system by the piezoelectric vibration effect. Also, in the vibrating piece of electrostatic drive type using electrostatic force (Coulomb force), Lorentz drive type using magnetic force, or the like, the configurations and the advantages of the invention may be achieved.

In addition, the shape of the vibration gyro element as the vibrating piece is not limited to the so-called WT type explained in the embodiment. Also, in a sensor device of tuning fork type or beam type, or a sensor device using a vibrating piece that electrostatically detects with a comb-like electrode like an MEMS gyro, according to the configuration including the IC chip as a semiconductor device having the cylindrical support part of the invention, the same advantages as those in the above described embodiment may be obtained.

Further, in the respective embodiments, the vibration gyro element 20 has been taken as an example as the vibrating piece (sensor element) provided in the sensor device, not limited, but, for example, an acceleration sensing element that reacts with acceleration, a pressure sensing element that reacts with pressure, a weight sensing element that reacts with weight, or the like may be used.

What is claimed is:

1. A sensor device comprising:
a semiconductor device having a first electrode and a second electrode on a first surface;
a frame-like fixing member provided to surround the first electrode and the second electrode;
a vibrating piece electrically connected to the first electrode;
a lid body bonded to the first surface via the fixing member and forming a space that covers the vibrating piece; and
a lead wire electrically connected to the second electrode and extending through inside of the fixing member to outside of the space.

2. The sensor device according to claim 1, further comprising an external mounting terminal on a second surface opposite to the first surface of the semiconductor device,
wherein the led wire is electrically connected to the external mounting terminal via a third surface connecting the first surface and the second surface.

3. The sensor device according to claim 1, further comprising an insulating resin layer between at least one of the external mounting terminal and the lead wire and at least one of the second surface and the third surface.

4. The sensor device according to claim 1, further comprising an insulating resin layer between the second electrode and the first surface.

5. The sensor device according to claim 1, further comprising a plated layer on a surface of the lead wire different from a surface of the lead wire being in contact with the fixing member.

6. A manufacturing method of a sensor device comprising:
providing a frame-like fixing member surrounding a first electrode and a second electrode on a first surface of a semiconductor device having the first electrode and the second electrode on the first surface;
electrically connecting a vibrating piece to the first electrode;
electrically connecting a first end of a lead wire to the second electrode and providing the lead wire in contact with the fixing member between a second end opposite to the first end and the first end; and
bonding a lid body forming a space that covers the vibrating piece to the first surface via the fixing member.

7. The manufacturing method according to claim 6, wherein providing the lead wire includes providing an external mounting terminal on a second surface opposite to the first surface of the semiconductor device and electrically connecting the lead are to the external mounting terminal via a third surface connecting the first surface and the second surface.

8. The manufacturing method according to claim 6, further comprising providing an insulating resin layer between at least one of the external mounting terminal and the lead wire and at least one of the second surface and the third surface before providing the lead wire.

9. The manufacturing method according to claim 6, further comprising providing a plated layer on a surface different from a surface of the lead wire in contact with the fixing member.
